(19) United States
(12) Patent Application Publication
(10) Pub. No.: US 2024/0355993 A1
(43) Pub. Date: Oct. 24, 2024

(54) LIGHT-EMITTING DEVICE, DISPLAY, AND PREPARATION METHOD FOR LIGHT-EMITTING DEVICE

(71) Applicant: Xiamen Extremely PQ Display Technology Co., Ltd., Xiamen (CN)

(72) Inventor: GANG MA, Xiamen (CN)

(21) Appl. No.: 18/759,835

(22) Filed: Jun. 29, 2024

Related U.S. Application Data
(63) Continuation of application No. PCT/CN2022/080043, filed on Mar. 10, 2022.

(51) Int. Cl. H01L 33/64; H01L 33/00; H01L 33/62

(52) U.S. Cl. CPC H01L 33/644; H01L 33/005; H01L 33/62; H01L 33/641; H01L 33/642; H01L 2933/0075

(57) ABSTRACT

A light-emitting device includes: a substrate that includes a first surface and a second surface and defines a through via; a light-emitting element disposed on the first surface of the substrate and disposed corresponding to the through via in the substrate; and a heat-conducting structure filled with the through via in the substrate. Moreover, an end of the heat-conducting structure extends from the through via to be tightly attached to the light-emitting element, and another end of the heat-conducting structure extends from the through via to be flush with the second surface of the substrate or to cover the second surface of the substrate. Therefore, the light-emitting device can conduct heat, generated during the light-emitting element works, by means of the heat-conducting structure disposed in the substrate below the light-emitting element, so that the heat dissipation efficiency of the light-emitting device is improved.

### CROSS-REFERENCE TO RELATED APPLICATION

This application is a continuation of International Application No. PCT/CN2022/080043, filed on Mar. 10, 2022, the disclosure of which is incorporated herein by reference in its entirety.

### TECHNICAL FIELD

The disclosure relates to the technical field of semiconductor devices, and more particularly to a light-emitting device, a display, and a preparation method for a light-emitting device.

### BACKGROUND

A light-emitting diode (LED) display screen has advantages of being rich in color, easy to splice, good in uniformity, low in power consumption, etc., and is widely applied to the fields of conference places, military command, security display, commercial display, etc. The LED display screen is provided with multiple LED chips therein. Since the multiple LED chips are arranged in a closed space enclosed by a circuit board and a display panel, heat generated when the LED chips work is accumulated, so that the multiple LED chips are easy to be damaged caused by the generated large amount of heat, thereby affecting brightness and service life of the LED display screen.

In the related art, the heat generated when the multiple LED chips in the LED display screen work is generally conducted through the circuit board, and the heat is dissipated through the circuit board or a housing of the LED display screen. However, a heat conductivity coefficient of the existing circuit board is very low, and the heat generated by the multiple LED chips cannot be effectively thermally conductive, which seriously affects the heat dissipation effect of the LED display screen.

### SUMMARY

In view of the above disadvantages in the related art, objectives of the present disclosure are to provide a light-emitting device, a display, and a preparation method for a light-emitting device.

In order to achieve the above objectives and other related objectives, the present disclosure provides a light-emitting device, including: a substrate that includes: a first surface and a second surface disposed opposite to the first surface; and the substrate defines a through via penetrating through the substrate; a light-emitting element, disposed on the first surface of the substrate and disposed corresponding to the through via; and a heat-conducting structure, filled with the through via; an end of the heat-conducting structure extends from the through via to be attached to the light-emitting element, and another end of the heat-conducting structure is flush with or covers the second surface of the substrate.

In an embodiment, the heat-conducting structure includes: a heat-conducting column filled with the through via; an end of the heat-conducting column extends from the through via to be attached to the light-emitting element; and another end of the heat-conducting column is flush with the second surface of the substrate.

In an embodiment, the light-emitting device further includes: a heat dissipation structure; and the heat dissipation structure is attached to the second surface of the substrate and is attached to the heat-conducting column.

In an embodiment, the heat-conducting column is a material selected from the group including heat-conducting metal and thermal grease.

In an embodiment, the heat-conducting structure includes: a heat-conducting column filled with the through via; and a heat-conducting metal layer disposed to cover the second surface of the substrate.

In an embodiment, a side of the heat-conducting metal layer facing away from the substrate is provided with a concave-convex structure.

In an embodiment, the heat-conducting structure includes: a first heat-conducting metal layer, disposed to cover an inner wall of the through via and the second surface of the substrate; and a second heat-conducting metal layer, disposed to cover the first heat-conducting metal layer and filled with the through via.

In an embodiment, the heat-conducting structure includes: a first heat-conducting metal layer, disposed to cover an inner wall of the through via and the second surface of the substrate; a second heat-conducting metal layer, disposed above the first heat-conducting metal layer; the first heat-conducting metal layer and the second heat-conducting metal layer together form a hollow structure, and the second heat-conducting metal layer forms a continuous structure with the first heat-conducting metal layer at two ends of the first heat-conducting metal layer; and a refrigerant medium, filled with the hollow structure and the through via.

In an embodiment, a side of the second heat-conducting metal layer of the heat-conducting structure facing away from the substrate is provided with a concave-convex structure.

In an embodiment, the light-emitting element includes: an electrode structure and a light-emitting structure; and the electrode structure is bonded to the first surface of the substrate, the light-emitting structure is disposed corresponding to the through via defined in the substrate, and the end of the heat-conducting structure extends from the through via to be attached to the light-emitting structure of the light-emitting element.

In an embodiment, the heat-conducting structure is the heat-conducting metal, the light-emitting device further includes: an insulation layer disposed between the heat-conducting structure and the electrode structure.

The present disclosure further provides a preparation method for a light-emitting device, including the following steps:
providing a substrate that includes a first surface and a second surface disposed opposite to the first surface and defines a through via penetrating through the substrate;
transferring a light-emitting element to the first surface of the substrate, thereby making the light-emitting element disposed corresponding to the through via; and
filling a heat-conducting material in the through via to form a heat-conducting structure, and extending an end of the heat-conducting structure from the through via to be attached to the light-emitting element, and extending another end of the heat-conducting structure to be flush with or to cover the second surface of the substrate.

In an embodiment, the filling a heat-conducting material in the through via to form a heat-conducting structure, further includes:
forming a heat-conducting column in the through via by evaporating or sputtering to make an end of the heat-conducting column to be attached to the light-emitting element, and make another end of the heat-conducting column extend to be flush with the second surface of the substrate; or
forming a heat-conducting column in the through via to make an end of the heat-conducting column to be attached to the light-emitting element, and make another end of the heat-conducting column extend to be flush with the second surface of the substrate.

In an embodiment, the preparation method for the light-emitting device further includes the following steps:
providing a heat dissipation structure; and
attaching the heat dissipation structure to the second surface of the substrate and the heat-conducting column that is flush with the second surface of the substrate.

In an embodiment, the filling a heat-conducting material in the through via to form a heat-conducting structure, includes:
forming a heat-conducting column on an inner wall of the through via by evaporating or sputtering;
forming a heat-conducting metal layer on the second surface of the substrate and a surface of the heat-conducting column that is flush with the second surface of the substrate by chemically evaporating; and
etching the heat-conducting metal layer to make a side of the heat-conducting metal layer facing away from the substrate form a concave-convex structure.

In an embodiment, the filling a heat-conducting material in the through via to form a heat-conducting structure, includes:
forming a first heat-conducting metal layer on the second surface of the substrate and an inner wall of the through via by evaporating or sputtering; and
forming a second heat-conducting metal layer on a surface of the first heat-conducting metal layer by chemically evaporating and filling the second heat-conducting metal layer in the through via.

In an embodiment, the filling a heat-conducting material in the through via to form a heat-conducting structure, includes:
forming a first heat-conducting metal layer on the second surface of the substrate and an inner wall of the through via by evaporating or sputtering;
providing a pattern template;
forming a second heat-conducting metal layer with a preset topography on a surface of the pattern template;
bonding the second heat-conducting metal layer to the first heat-conducting metal layer at two ends of the first heat-conducting metal layer to form a hollow structure between the first heat-conducting metal layer and the second heat-conducting metal layer; and
injecting a refrigerant medium into the hollow structure.

In an embodiment, a side of the second heat-conducting metal layer of the heat-conducting structure facing away from the substrate is provided with a concave-convex structure.

The present disclosure further provides a display, including the light-emitting device according to any one of the above-mentioned light-emitting devices.

### BENEFICIAL EFFECTS

Compared with the related art, the preparation method for the light-emitting device, the display, and the light-emitting device of the present disclosure at least have the following beneficial effects.

The light-emitting device of the present disclosure includes the substrate, the substrate includes the first surface and the second surface disposed opposite to the first surface, the substrate defines the through via, and the light-emitting element is disposed on the first surface of the substrate and is disposed corresponding to the through via in the substrate. The heat-conducting structure fills the through via defined on the substrate, and the end of the heat-conducting structure extends from the through via to be tightly attached to the light-emitting element, and the other end of the heat-conducting structure extends to be flush with the second surface of the substrate or to cover the second surface of the substrate. Specially, the heat-conducting structure adopts the heat-conducting material with a relatively high thermal conductivity, and heat generated by the light-emitting element can be directly transferred to the heat dissipation structure, so that a path for the heat dissipation is shortened, and the heat transmitted by the substrate itself is reduced. Meanwhile, the heat-conducting structure is in direct contact with the light-emitting element, so that the heat-conducting structure and the light-emitting element have the largest contact area, and an area for heat conduction is increased. In this way, efficient heat dissipation of the light-emitting device is achieved, the temperature of the light-emitting element is reduced, and the service life of the light-emitting element and the light-emitting device is prolonged.

In addition, the heat-conducting structure of the present disclosure may have multiple arrangements, and the heat-conducting structures with different structures may be provided according to different types of the substrate. At the same time, the heat-conducting material used to form the heat-conducting structure can also make various choices according to actual situations, thereby increasing the application range of the heat-conducting structure, making the heat-conducting structure suitable for different light-emitting devices with different types of the substrate, and improving effects of the heat dissipation and service life of various light-emitting devices.

Preparation methods for the display and the light-emitting device described in the present disclosure includes the above-mentioned preparation method for the light-emitting device, which can also achieve the above-mentioned technical effects.

### BRIEF DESCRIPTION OF DRAWINGS

FIG. 1 illustrates a schematic structural diagram of a light-emitting device according to an embodiment 1 of the present disclosure.

FIG. 2 illustrates a schematic structural diagram of a light-emitting device according to an embodiment 2 of the present disclosure.

FIG. 3 illustrates a schematic structural diagram of a light-emitting device according to an embodiment 3 of the present disclosure.

FIG. 4 illustrates a schematic structural diagram of a light-emitting device according to an embodiment 4 of the present disclosure.

FIG. 5 illustrates a schematic structural diagram of defining a through via in a substrate according to an embodiment 5 of the present disclosure.

FIG. 6 illustrates a schematic structural diagram of defining a through via in a substrate according to an embodiment 6 of the present disclosure.

FIG. 7A illustrates a schematic structural diagram of bonding a light-emitting element to a first surface of a substrate according to an embodiment 7 of the present disclosure.

FIG. 7B illustrates a schematic structural diagram of defining a through via into a trapezoidal hole according to the embodiment 7 of the present disclosure.

FIG. 7C illustrates a schematic structural diagram of forming a first heat-conducting metal layer on a second surface of the substrate and an inner wall of the through via according to the embodiment 7 of the present disclosure.

FIG. 7D illustrates a schematic structural diagram of forming a second heat-conducting metal layer on the first heat-conducting metal layer according to the embodiment 7 of the present disclosure.

FIG. 8A illustrates a schematic structural diagram of forming an insulation layer on an inner wall of an electrode structure of a light-emitting element disposed corresponding to a through via according to an embodiment 8 of the present disclosure.

FIG. 8B illustrates a schematic structural diagram of forming a first heat-conducting metal layer on a second surface of a substrate and an inner wall of the through via according to the embodiment 8 of the present disclosure.

FIG. 8C illustrates a schematic structural diagram of a pattern template according to the embodiment 8 of the present disclosure.

FIG. 8D illustrates a schematic structural diagram of forming a second heat-conducting metal layer on a surface of the pattern template according to the embodiment 8 of the present disclosure.

FIG. 8E illustrates a schematic structural diagram of bonding a structure illustrated in FIG. 8B to a structure illustrated in FIG. 8D to form a hollow structure between the first heat-conducting metal layer and the second heat-conducting metal layer according to the embodiment 8 of the present disclosure.

### DESCRIPTION OF REFERENCE SIGNS ARE AS FOLLOWS

| | |
|---|---|
| 100 | Substrate |
| 101 | Through via |
| 110 | First suface |
| 120 | Second surface |
| 200 | Light-emitting element |
| 201 | Electrode structure |
| 202 | Light-emitting structure |
| 300 | Heat-conducting structure |
| 310 | Heat-conducting column |
| 320 | Heat-conducting metal layer |
| 321 | First heat-conducting metal layer |
| 322 | Second heat-conducting metal layer |
| 323 | Hollow structure |
| 324 | Refrigerant medium |
| 400 | Heat dissipation structure |
| 401 | Heat dissipation substrate |
| 402 | Heat dissipation fin |
| 500 | Insulation layer |
| 600 | Photoresist mask |
| 601 | Opening |
| 700 | Pattern template |

### DETAILED DESCRIPTION OF EMBODIMENTS

The embodiments of the present disclosure are described below with reference to specific embodiments, and those skilled in the related art can easily understand other advantages and effects of the present disclosure from the content disclosed in the present disclosure. The present disclosure may also be implemented or applied by different specific embodiments, and various details in the description may also be modified or changed based on different viewpoints and applications without departing from the spirit of the present disclosure. It should be noted that, in the case of no conflict, the following embodiments and features in the embodiments may be combined with each other.

It should be noted that the attached drawings provided in the embodiments of the present disclosure merely illustrate the basic concept of the present disclosure in a schematic manner. Although the attached drawings only illustrate components related to the present disclosure rather than illustrate the number, shape and size of the components in actual implementation, the form, quantity, and proportion of the components can be changed at will in the actual implementation, and a layout form of the components may also be more complex. The structure, proportion, size, etc. shown in the attached drawings of the specification are only used to cooperate with the content disclosed in the specification for those skilled in the art to understand and read, and are not intended to limit conditions that can be implemented in the present disclosure. Therefore, the attached drawings do not have technical significance. Any modifications to the structure, changes in proportion or adjustments in size, without affecting the efficacy and objectives that can be achieved by the present disclosure, shall still fall within the scope of the technical content disclosed in the present disclosure.

### Embodiment 1

The present embodiment provides a light-emitting device, including: a substrate, a light-emitting element, and a heat-conducting structure. The substrate includes a first surface and a second surface disposed opposite to the first surface, the substrate defines a through via penetrating through the substrate, and the through via is connected to the first surface and the second surface of the substrate. The light-emitting element is disposed on the first surface of the substrate and is disposed corresponding to the through via. An end of the heat-conducting structure extends from the through via to be tightly attached to the light-emitting element, and another end of the heat-conducting structure extends to be flush with or to cover the second surface of the substrate. Therefore, the light-emitting element disposed on the first surface of the substrate can conduct heat, generated during the light-emitting element works, to the second surface of the substrate through the heat-conducting structure, so that light-emitting brightness and service life of the light-emitting device can be improved.

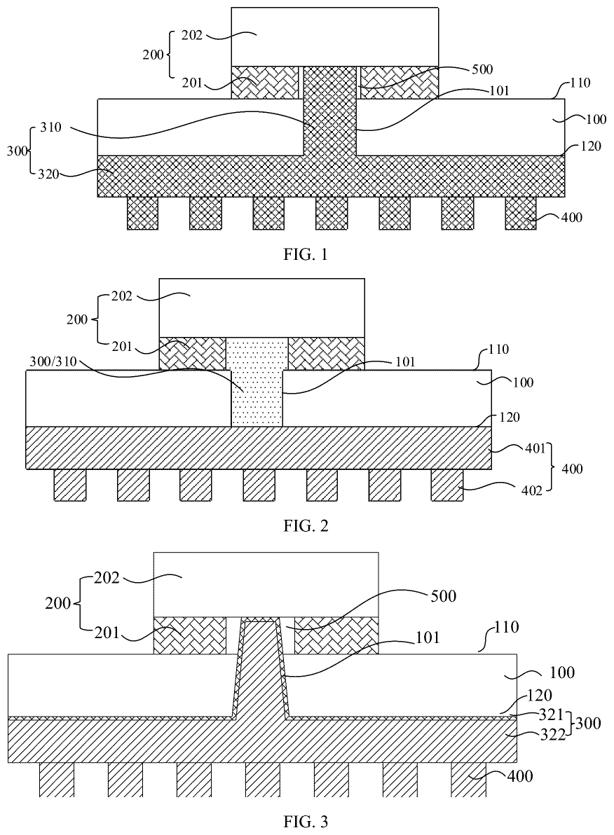

Specifically, with reference to FIG. 1, the substrate 100 includes a driving circuit for electrically connecting the light-emitting element 200 and controlling the light-emitting element 200 to be turned on and off. Optionally, the substrate 100 can be one of a printed circuit board (PCB) substrate, a thin film transistor (TFT) substrate, and a flexible polyimide (PI) substrate. In the present embodiment, the substrate 100 is described by taking the TFT substrate as an example.

The light-emitting element 200 serves as a light source of the light-emitting device, is disposed on the first surface 110 of the substrate 100, and is disposed corresponding to the through via 101 defined on the substrate 100. In the present embodiment, the light-emitting element 200 includes a light-emitting structure 202 and an electrode structure 201. Specially, a number of the electrode structure 201 can be two and the two electrode structures 201 of the light-emitting element 200 are bonded to the first surface 110 of the substrate 100, the light-emitting structure 202 of the light-emitting element 200 is disposed corresponding to the through via 101 of the substrate 100, and the light-emitting structure 202 can be used as a bottom wall of the through via 101 for subsequent direct growth of a heat-conducting material. Optionally, the light-emitting element 200 is a light-emitting diode (LED) chip or a micro-LED chip, such as a micro red LED chip, a micro blue LED chip, or a micro green LED chip. It should be noted that, in the present disclosure, there are multiple light-emitting elements 200, and the present disclosure takes, using only one light-emitting element 200 disposed on the substrate 100, as an example, which cannot be regarded as a limitation to the present disclosure.

The heat-conducting structure 300 fills the through via 101, the end of the heat-conducting structure 300 extends from the through via 101 to be tightly attached to the light-emitting structure 202 of the light-emitting element 200, and the other end of the heat-conducting structure 300 extends from the through via 101 to be flush with the second surface 120 of the substrate 100. In the present embodiment, the heat-conducting structure 300 is formed in the through via 101, where is defined corresponding to the surface of the light-emitting structure 202 of the light-emitting element 200. Therefore, when the heat-conducting structure 300 is formed in the through via 101, the heat-conducting structure 300 can directly grow on the surface of the light-emitting structure 202, so that the heat-conducting structure 300 is in direct contact with the light-emitting structure 202 of the light-emitting element 200, and the heat dissipation efficiency can be further improved. It should be noted that a thermal conductivity coefficient of the heat-conducting material of the heat-conducting structure 300 needs to be greater than a thermal conductivity coefficient of the heat-conducting material of the substrate 100, so as to improve the heat transfer efficiency between the substrate 100 and the light-emitting element 200. In the present embodiment, the heat-conducting structure 300 includes a first portion filled in the through via 101 and a second portion covering the second surface 120 of the substrate 100, the first portion is formed as a heat-conducting column 310, the second portion is formed as a heat-conducting metal layer 320, and the first portion and the second portion are formed into an integrated structure, and the first portion and the second portion are made from the heat-conducting material, for example, titanium or copper. An insulation layer 500 is further disposed between the heat-conducting column 310 and the electrode structure 201 of the light-emitting element 200 to electrically isolate the electrode structure 201 from the heat-conducting metal (i.e., the heat-conducting column 310).

In the present embodiment, a side of the heat-conducting metal layer 320 facing away from the substrate 100 is further provided with a heat dissipation structure 400, and the heat dissipation structure 400 is formed as a concave-convex structure, so that a contact area between a radiator and the air can be increased, which is beneficial to improving the heat dissipation efficiency of the light-emitting device. In other embodiments, the heat dissipation structure 400 can also be an independent radiator, and can be tightly attached to the heat-conducting structure 300 for heat dissipation. For example, the heat dissipation structure 400 can be a fin radiator as shown in FIG. 2, the fin radiator includes a heat dissipation substrate 401 and a heat dissipation fin 402 disposed on a side of the heat dissipation substrate 401 facing away from the substrate 100, and the heat dissipation substrate 401 is tightly attached to the heat-conducting metal layer 320 shown in FIG. 1, so that the heat dissipation substrate 401 is tightly connected to the heat-conducting structure 300 shown in FIG. 1. Therefore, the heat is conducted to the heat dissipation fin 402 through the heat dissipation substrate 401 for the heat dissipation.

In the present embodiment, the heat-conducting column 310 and the heat-conducting metal layer 320 are both grown by vacuum evaporation or chemical vapor deposition, so that the heat-conducting column 310 and the light-emitting element 200 can grow together to achieve seamless connection, thereby avoiding a problem that the heat conduction area is reduced due to the fact that the light-emitting element 200 and the heat-conducting column 310 cannot form effective contact.

### Embodiment 2

The present embodiment provides a light-emitting device, and the light-emitting device also includes a substrate, a light-emitting element, and a heat-conducting structure. The substrate includes a first surface and a second surface disposed opposite to the first surface, the substrate defines a through via penetrating through the substrate, and the through via is connected to the first surface and the second surface of the substrate. The light-emitting element is disposed on the first surface of the substrate and is disposed corresponding to the through via. An end of the heat-conducting structure extends from the through via to be tightly attached to the light-emitting element, and another end of the heat-conducting structure extends to be flush with the second surface of the substrate. The above similarities as the embodiment 1 are not repeated here, and differences from the embodiment 1 are as follows.

With reference to FIG. 2, in the present embodiment, the heat-conducting structure 300 is a heat-conducting column 310 formed in the through via 101, and the heat-conducting column 310 is thermal grease. In addition, a heat dissipation structure 400 is formed on the second surface 120 of the substrate 100, and the heat dissipation structure 400 is attached to the second surface 120 of the substrate 100 as well as the thermal grease (i.e., the heat-conducting column 310) that is flush with the second surface 120 of the substrate 100. In the present embodiment, the heat dissipation structure 400 is a fin-type radiator, the fin-type radiator includes a heat dissipation substrate 401 and a heat dissipation fin 402 disposed on a side of the heat dissipation substrate 401 facing away from the substrate 100, and the heat dissipation fin 402 can further dissipate heat generated by the light-emitting element 200, which is beneficial to improving the heat dissipation efficiency of the light-emitting element 200.

### Embodiment 3

The present embodiment provides a light-emitting device, and the light-emitting device also includes a substrate, a light-emitting element, and a heat-conducting structure. The substrate includes a first surface and a second surface disposed opposite to the first surface, the substrate defines a through via penetrating through the substrate, and the through via is connected to the first surface and the second surface of the substrate. The light-emitting element is disposed on the first surface of the substrate and disposed corresponding to the through via. An end of the heat-conducting structure extends from the through via to be tightly attached to the light-emitting element, and another end of the heat-conducting structure extends to cover the second surface of the substrate. The above similarities as the embodiment 1 are not repeated here, and differences from the embodiment 1 are as follows.

With reference to FIG. 3, in the present embodiment, the substrate 100 is the flexible PI substrate, and the heat-conducting structure 300 includes a first heat-conducting metal layer 321 and a second heat-conducting metal layer 322. Specially, the first heat-conducting metal layer 321 covers the second surface 120 of the substrate 100 and an inner wall of the through via 101, and the first heat-conducting metal layer 321 is formed by evaporating or sputtering, so that the first heat-conducting metal layer 321 and a bottom of the light-emitting element 200 exposed in the through via 101 form a tight connection. Optionally, a thickness of the first heat-conducting metal layer 321 is less than 1 micrometer (m). In the present embodiment, an insulation layer 500 is further disposed between the first heat-conducting metal layer 321 and an electrode structure 201 of the light-emitting element 200 to electrically isolate the electrode structure 201 from the heat-conducting metal (i.e., the first heat-conducting metal layer 321).

The second heat-conducting metal layer 322 covers the first heat-conducting metal layer 321 and fills the through via 101, and the second heat-conducting metal layer 322 forms a heat dissipation structure 400 on a side of the second heat-conducting metal layer 322 facing away from the substrate 100, and the heat dissipation structure 400 is of a concave-convex structure, so that a contact area between the second heat-conducting metal layer 322 and the outside can be increased, and the heat conduction or heat dissipation effect is improved.

### Embodiment 4

The present embodiment provides a light-emitting device, and the light-emitting device also includes a substrate, a light-emitting element, and a heat-conducting structure. The substrate includes a first surface and a second surface disposed opposite to the first surface, the substrate defines a through via penetrating through the substrate, and the through via is connected to the first surface and the second surface of the substrate. The light-emitting element is disposed on the first surface of the substrate and is disposed corresponding to the through via. An end of the heat-conducting structure extends from the through via to be tightly attached to the light-emitting element, and another end of the heat-conducting structure extends to cover the second surface of the substrate. The above similarities as the embodiment 1 are not repeated here, and differences from the embodiment 1 are as follows.

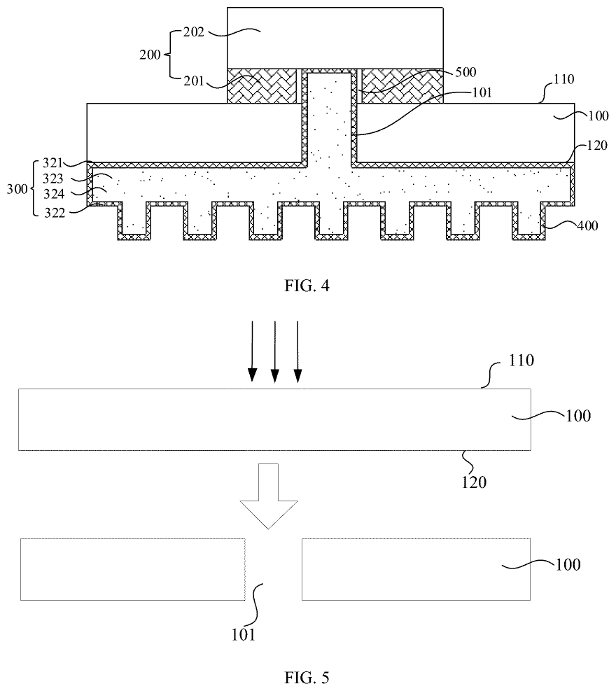

With reference to FIG. 4, in the present embodiment, the heat-conducting structure 300 includes a first heat-conducting metal layer 321, a second heat-conducting metal layer 322, and a refrigerant medium 324. Specially, the first heat-conducting metal layer 321 covers an inner wall of the through via 101 and the second surface 120 of the substrate 100, the second heat-conducting metal layer 322 is disposed above the first heat-conducting metal layer 321, a hollow structure 323 is formed between the second heat-conducting metal layer 322 and the first heat-conducting metal layer 321, and the second heat-conducting metal layer 322 forms a continuous structure with the first heat-conducting metal layer 321 at two ends of the first heat-conducting metal layer 321. The refrigerant medium 324 fills the hollow structure 323 and the through via 101.

In the present embodiment, an insulation layer 500 is also provided between the first heat-conducting metal layer 321 and the electrode structure 201 of the light-emitting element 200 to electrically isolate the electrode structure 201 from the heat-conducting metal (i.e., the heat-conducting metal layer 320). Optionally, the refrigerant medium 324 can be one of water, oil, and the air. In the present embodiment, the refrigerant medium 324 is oil, and molecular motion caused by heating the oil can achieve a faster heat conduction effect, thereby improving the heat dissipation efficiency.

### Embodiment 5

The present embodiment provides a preparation method for a light-emitting device, including the following steps.

Step 101, a substrate is provided; and the substrate includes a first surface and a second surface disposed opposite to the first surface, and the substrate defines a through via penetrating through the substrate.

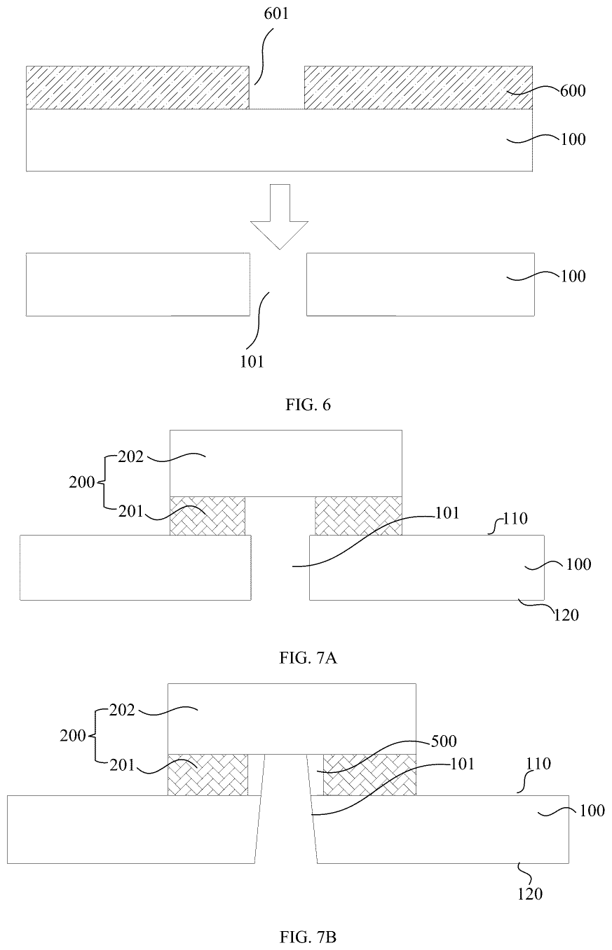

With reference to FIG. 5, a substrate 100 is provided, the substrate 100 includes a first surface 110 and a second surface 120 disposed opposite to the first surface 110, and a through via 101 is defined on the substrate 100 through laser. In other embodiments, a photoresist mask 600 is formed on the substrate 100, an opening 601 is defined on the photoresist mask 600, and the substrate 100 is etched along the opening 601 to form the through via 101 on the substrate 100, as shown in FIG. 6.

Step 102, a light-emitting element is transferred to the first surface of the substrate, and the light-emitting element is disposed corresponding to the through via.

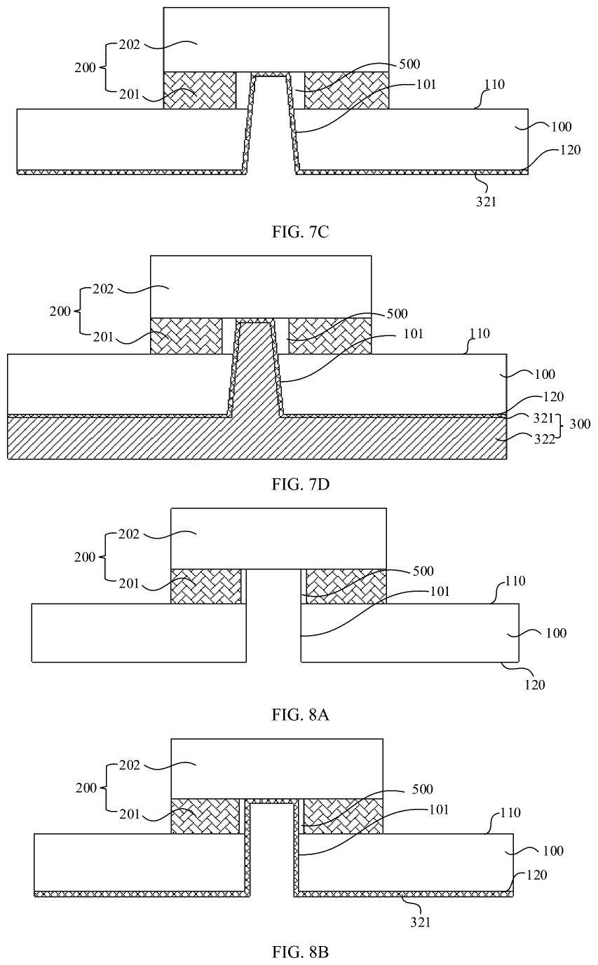

With reference to FIG. 7A, the light-emitting element 200 is transferred and bonded to the first surface 110 of the substrate 100, so that the light-emitting element 200 is disposed corresponding to a position of the through via 101, and a light-emitting structure 202 of the light-emitting element 200 covers the through via 101.

Step 103, the through via is filled with a heat-conducting material to form a heat-conducting structure, and an end of the heat-conducting structure extends from the through via to be connected with the light-emitting element, and another end of the heat-conducting structure extends to cover the second surface of the substrate.

In the present embodiment, with reference to FIG. 1, the heat-conducting metal (also refereed as to the heat-conducting material) is evaporated in the through via 101 through the second surface 120 of the substrate 100, so that the heat-conducting metal fills the through via 101 to form the heat-conducting column 310, and the heat-conducting metal continues to be chemically evaporated, so that the heat-conducting metal layer 320 is formed on the second surface 120 of the substrate 100, and the heat-conducting column 310 and the heat-conducting metal layer 320 are formed into the integrated structure. Since the material formed in the through via 101 of the present embodiment is the heat-conducting metal, in order to make the heat-conducting metal electrically insulated from the electrode structure 201 of the light-emitting element 200, before the heat-conducting metal layer 320 is formed, an insulation layer 500 is further formed between the electrode structure 201 of the light-emitting element 200 and the heat-conducting metal. Specifically, before the heat-conducting metal is evaporated in the through via 101 defined on the second surface 120 of the substrate 100, a thin insulation layer is deposited in the through via 101, and the thin insulation layer deposited on an inner wall of the through via 101 and deposited on a surface of the light-emitting structure 202 of the light-emitting element 200 through the through via 101 is etched to obtain the insulation layer 500 formed on the surface of the electrode structure 201 penetrating through the through via 101 shown in FIG. 1.

The heat-conducting metal layer 320 is etched, so that a heat dissipation structure 400 is formed on a side of the heat-conducting metal layer 320 facing away from the substrate 100, and the heat dissipation structure 400 is formed as a concave-convex structure to increase the contact area between the heat-conducting metal layer 320 and the outside and increase the heat dissipation effect.

### Embodiment 6

The present embodiment provides a preparation method for a light-emitting device, the similarities as the embodiment 5 are not repeated here, and differences from the embodiment 5 are as follows.

In the step 103, the through via is filled with a heat-conducting material to form a heat-conducting structure, and an end of the heat-conducting structure extends from the through via to be connected with the light-emitting element, and another end of the heat-conducting structure extends to be flush with the second surface of the substrate.

In the present embodiment, with reference to FIG. 2, the thermal grease is formed in the through via 101 in a spin coating or spraying manner. Moreover, due to a fact that an insulation property of the thermal grease, before the through via 101 is filled with the thermal grease, the insulation layer 500 does not need to be formed first, thereby simplifying the preparation method and saving the manufacturing cost of the light-emitting device.

After forming the thermal grease, the preparation method further includes: providing a fin-type radiator; and the fin-type radiator includes a heat dissipation substrate 401 and a heat dissipation fin 402 disposed on a side of the heat dissipation substrate 401 facing away from the substrate 100. In addition, the second surface 120 of the substrate 100 is attached to a surface of the heat dissipation substrate 401, thereby making the thermal grease tightly attached to the heat dissipation substrate 401. Therefore, the heat generated by the light-emitting element 200 is conducted to the heat dissipation substrate 401 through the thermal grease, and the heat dissipation effect is further improved through the heat dissipation fin 402.

### Embodiment 7

The present embodiment provides a preparation method for a light-emitting device, the similarities as the embodiment 5 are not repeated here, and differences from the embodiment 5 are as follows.

In the step 101, a substrate is provided; the substrate includes a first surface and a second surface disposed opposite to the first surface; and the substrate defines a through via penetrating through the substrate.

With reference to FIG. 6, the substrate 100 is provided, the substrate 100 includes the first surface 110 and the second surface 120 disposed opposite to the first surface 110, the substrate 100 is the flexible PI substrate, a photoresist mask 600 is formed above the flexible PI substrate, an opening 601 is defined on the photoresist mask 600, and the substrate 100 is etched along the opening 601 to form a through via 101 on the substrate 100.

In the step 103, the through via is filled with a heat-conducting material to form a heat-conducting structure, and an end of the heat-conducting structure extends from the through via to be connected with the light-emitting element, and another end of the heat-conducting structure extends to cover the second surface of the substrate.

With reference to FIG. 7B, an insulation layer is deposited in the through via 101, the insulation layer deposited on an inner wall of the through via 101 and deposited on a surface of a light-emitting structure 202 of the light-emitting element 200 through the through via 101 is etched to obtain the insulation layer 500 formed on the surface of the electrode structure 201 penetrating through the through via 101.

In order to make the heat-conducting material more easily deposited on the inner wall of the through via 101 or on the insulation layer 500, after forming the insulation layer 500, the present embodiment further includes pre-treating the through via 101 and the insulation layer 500 disposed on the surface of the electrode structure 201, so that the through via 101 and a through hole constituted by the insulation layer 500 located on the surface of the electrode structure 201 are formed as a trapezoidal hole. Specifically, the trapezoidal hole may be formed by etching the inner wall of the through via 101 and the insulation layer 500 disposed on the surface of the electrode structure 201.

With reference to FIG. 7C, a first heat-conducting metal layer 321 is formed on the second surface 120 of the substrate 100 and the inner wall of the trapezoidal hole by sputtering or evaporating.

With reference to FIG. 7D, a second heat-conducting metal layer 322 is formed on a surface of the first heat-conducting metal layer 321 in a chemical vapor deposition manner.

With reference to FIG. 3, the second heat-conducting metal layer 322 is etched, so that the second heat-conducting metal layer 322 forms a heat dissipation structure 400 on a side of the second surface 120 facing away from the substrate 100, the heat dissipation structure 400 is formed as a concave-convex structure, and the concave-convex structure can increase the contact area with the outside and increase the heat dissipation effect.

### Embodiment 8

The present embodiment provides a preparation method for a light-emitting device, the similarities as the embodiment 5 are not repeated here, and differences from the embodiment 5 are as follows.

In the step 103, the through via is filled with a heat-conducting material to form a heat-conducting structure, and an end of the heat-conducting structure extends from the through via to be connected with the light-emitting element, and another end of the heat-conducting structure extends to cover the second surface of the substrate.

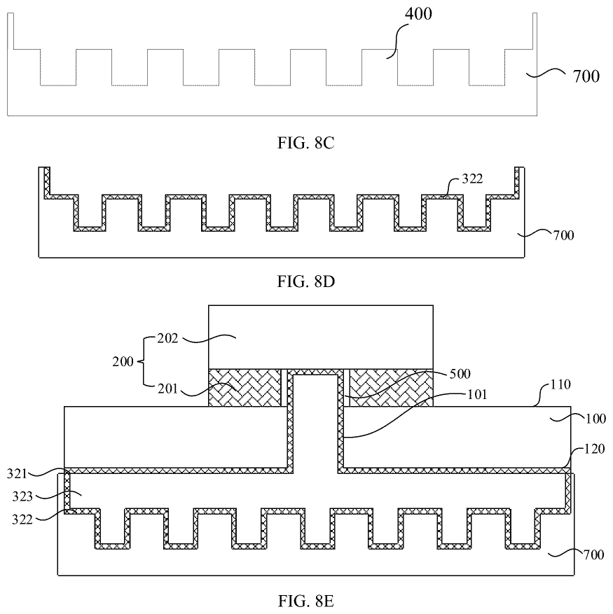

With reference to FIG. 8A, an insulation layer 500 is formed on a side wall disposed corresponding to the through via 101, of the electrode structure 201 of the light-emitting element 200 to ensure that the electrode structure 201 is electrically insulated from the subsequently formed heat-conducting metal layer 320.

With reference to FIG. 8B, the first heat-conducting metal layer 321 is formed on the second surface 120 of the substrate 100 and the inner wall of the through via 101 by sputtering or evaporating.

With reference to FIG. 8C, a pattern template 700 is provided, and a surface of the pattern template 700 includes a concave-convex structure with a preset morphology.

With reference to FIG. 8D, a second heat-conducting metal layer 322 is formed by chemical evaporation in a concave-convex structure on the surface of the pattern template 700.

With reference to FIG. 8E, the pattern template 700 vapored with the second heat-conducting metal layer 322 shown in FIG. 8D is bonded to the first heat-conducting metal layer 321 shown in FIG. 8B, a hollow structure 323 is formed between the first heat-conducting metal layer 321 and the second heat-conducting metal layer 322, and the second heat-conducting metal layer 322 forms a continuous structure with the first heat-conducting metal layer 321 at the two ends of the first heat-conducting metal layer 321. Moreover, the hollow structure 323 defines a hole, and a refrigerant medium 324 is injected into the hollow structure 323 through the hole. After the refrigerant medium 324 fills the hollow structure 323 completely, the hollow structure 323 is welded sealed. At the same time, the pattern template 700 is removed by wet etching to form the heat-conducting structure 300. In the present embodiment, the oil is used as the refrigerant medium 324, and the molecular motion caused by heating the oil can achieve the faster heat conduction effect, and the heat dissipation effect of the light-emitting device can be further enhanced.

### Embodiment 9

The present embodiment provides a display, including the light-emitting device according to any one of the embodiments 1 to 4. Similarly, in the present embodiment, the heat generated when the light-emitting element 200 works is conducted by using the heat-conducting structure 300 in the substrate 100 below the light-emitting element 200, so that the heat dissipation efficiency of the light-emitting device and the display can be effectively improved.

The above embodiments are merely illustrative of the principles and effects of the present disclosure, and are not intended to limit the present disclosure. Those skilled in the related art may modify or change the above embodiments without departing from the spirit and the scope of the present disclosure. Therefore, all equivalent modifications or changes made by those skilled in the related art without departing from the spirit and the technical concepts disclosed in the present disclosure shall still be covered by the description of the present disclosure.

What is claimed is:

1. A light-emitting device, comprising:
a substrate, wherein the substrate comprises: a first surface and a second surface disposed opposite to the first surface; and the substrate defines a through via penetrating through the substrate;
a light-emitting element, disposed on the first surface of the substrate and disposed corresponding to the through via; and
a heat-conducting structure, filled with the through via; wherein an end of the heat-conducting structure extends from the through via to be attached to the light-emitting element, and another end of the heat-conducting structure is flush with or covers the second surface of the substrate.

2. The light-emitting device according to claim 1, wherein the heat-conducting structure comprises: a heat-conducting column filled with the through via, an end of the heat-conducting column extends from the through via to be attached to the light-emitting element; and another end of the heat-conducting column is flush with the second surface of the substrate.

3. The light-emitting device according to claim 2, further comprising: a heat dissipation structure, wherein the heat dissipation structure is attached to the second surface of the substrate and is attached to the heat-conducting column.

4. The light-emitting device according to claim 2, wherein the heat-conducting column is a material selected from the group comprising heat-conducting metal and thermal grease.

5. The light-emitting device according to claim 1, wherein the heat-conducting structure comprises:
a heat-conducting column, filled with the through via; and
a heat-conducting metal layer, disposed to cover the second surface of the substrate.

6. The light-emitting device according to claim 5, wherein a side of the heat-conducting metal layer facing away from the substrate is provided with a concave-convex structure.

7. The light-emitting device according to claim 1, wherein the heat-conducting structure comprises:
a first heat-conducting metal layer, disposed to cover an inner wall of the through via and the second surface of the substrate; and
a second heat-conducting metal layer, disposed to cover the first heat-conducting metal layer and filled with the through via.

8. The light-emitting device according to claim 1, wherein the heat-conducting structure comprises:
a first heat-conducting metal layer, disposed to cover an inner wall of the through via and the second surface of the substrate;
a second heat-conducting metal layer, disposed above the first heat-conducting metal layer; wherein the first heat-conducting metal layer and the second heat-conducting metal layer together form a hollow structure, and the second heat-conducting metal layer forms a continuous structure with the first heat-conducting metal layer at two ends of the first heat-conducting metal layer; and
a refrigerant medium, filled with the hollow structure and the through via.

9. The light-emitting device according to claim 7, wherein a side of the second heat-conducting metal layer of the heat-conducting structure facing away from the substrate is provided with a concave-convex structure.

10. The light-emitting device according to claim 8, wherein a side of the second heat-conducting metal layer of the heat-conducting structure facing away from the substrate is provided with a concave-convex structure.

11. The light-emitting device according to claim 1, wherein the light-emitting element comprises: an electrode structure and a light-emitting structure; and
wherein the electrode structure is bonded to the first surface of the substrate, the light-emitting structure is disposed corresponding to the through via defined in the substrate, and the end of the heat-conducting structure extends from the through via to be attached to the light-emitting structure of the light-emitting element.

12. The light-emitting device according to claim 11, wherein the heat-conducting structure is heat-conducting metal, the light-emitting device further comprises: an insulation layer disposed between the heat-conducting structure and the electrode structure.

13. A preparation method for a light-emitting device, comprising the following steps:
providing a substrate, wherein the substrate comprises: a first surface and a second surface disposed opposite to the first surface, and the substrate defines a through via penetrating through the substrate;
transferring a light-emitting element to the first surface of the substrate, and making the light-emitting element disposed corresponding to the through via; and
filling a heat-conducting material in the through via to form a heat-conducting structure, and extending an end of the heat-conducting structure from the through via to be attached to the light-emitting element, and extending another end of the heat-conducting structure to be flush with or to cover the second surface of the substrate.

14. The preparation method for the light-emitting device according to claim 13, wherein the filling a heat-conducting material in the through via to form a heat-conducting structure, further comprises:
forming a heat-conducting column in the through via by evaporating or sputtering to make an end of the heat-conducting column to be attached to the light-emitting element, and make another end of the heat-conducting column extend to be flush with the second surface of the substrate; or
forming a heat-conducting column in the through via to make an end of the heat-conducting column to be attached to the light-emitting element, and make another end of the heat-conducting column extend to be flush with the second surface of the substrate.

15. The preparation method for the light-emitting device according to claim 14, further comprising:
providing a heat dissipation structure; and
attaching the heat dissipation structure to the second surface of the substrate and the heat-conducting column that is flush with the second surface of the substrate.

16. The preparation method for the light-emitting device according to claim 13, wherein the filling a heat-conducting material in the through via to form a heat-conducting structure, comprises:
forming a heat-conducting column on an inner wall of the through via by evaporating or sputtering;
forming a heat-conducting metal layer on the second surface of the substrate and a surface of the heat-conducting column that is flush with the second surface of the substrate by chemically evaporating; and
etching the heat-conducting metal layer to make a side of the heat-conducting metal layer facing away from the substrate form a concave-convex structure.

17. The preparation method for the light-emitting device according to claim 13, wherein the filling a heat-conducting material in the through via to form a heat-conducting structure, comprises:
forming a first heat-conducting metal layer on the second surface of the substrate and an inner wall of the through via by evaporating or sputtering; and
forming a second heat-conducting metal layer on a surface of the first heat-conducting metal layer by chemically evaporating and filling the second heat-conducting metal layer in the through via.

18. The preparation method for the light-emitting device according to claim 13, wherein the filling a heat-conducting material in the through via to form a heat-conducting structure, comprises:
forming a first heat-conducting metal layer on the second surface of the substrate and an inner wall of the through via by evaporating or sputtering;
providing a pattern template;
forming a second heat-conducting metal layer with a preset topography on a surface of the pattern template;
bonding the second heat-conducting metal layer to the first heat-conducting metal layer at two ends of the first heat-conducting metal layer to form a hollow structure between the first heat-conducting metal layer and the second heat-conducting metal layer; and
injecting a refrigerant medium into the hollow structure.

19. The preparation method for the light-emitting device according to claim 17, wherein a side of the second heat-conducting metal layer of the heat-conducting structure facing away from the substrate is provided with a concave-convex structure.

20. The preparation method for the light-emitting device according to claim 18, wherein a side of the second heat-conducting metal layer of the heat-conducting structure facing away from the substrate is provided with a concave-convex structure.

21. A display, comprising: the light-emitting device according to claim 1.
